(19) United States
(12) Patent Application Publication
(10) Pub. No.: US 2014/0254121 A1
(43) Pub. Date: Sep. 11, 2014

(54) PRINTED CIRCUIT BOARD

(71) Applicant: Samsung Electro-Mechanics Co., Ltd., Suwon (KR)

(72) Inventors: Joong Hyuk Jung, Busan (KR); Kwang Son You, Busan (KR); Jong Hyung Kim, Busan (KR); Sang Hoon Park, Changwon (KR); Hyea Hyen Kang, Kimhae (KR)

(73) Assignee: Samsung Electro-Mechanics Co., Ltd., Suwon (KR)

(21) Appl. No.: 14/158,127

(22) Filed: Jan. 17, 2014

(30) Foreign Application Priority Data
Mar. 5, 2013 (KR) 10-2013-0023239

(51) Int. Cl. H05K 1/02

(52) U.S. Cl. CPC H05K 1/0271
USPC 361/774; 174/268; 174/262

(57) ABSTRACT

Disclosed herein is a printed circuit board having an insulating layer crack preventing port. The printed circuit board includes: an insulating layer part having at least one pair of insulating layers stacked therein; circuit patterns formed on the insulating layers, respectively; and crack preventing ports formed at positions at which they are not affected by the respective circuit patterns of the insulating layer part and supporting the insulating layer part from external impact.

### CROSS REFERENCE(S) TO RELATED APPLICATIONS

This application claims the foreign priority benefit under 35 U.S.C. Section 119 of Korean Patent Application Serial No. 10-2013-0023239, entitled “Printed Circuit Board” filed on Mar. 5, 2013, which is hereby incorporated by reference in its entirety into this application.

### BACKGROUND OF THE INVENTION

1. Technical Field

The present invention relates to a printed circuit board, and more particularly, to a printed circuit board having an insulating layer crack preventing port.

2. Description of the Related Art

Generally, in accordance with slimness and lightness of electronic apparatuses of an information technology (IT) field including a cellular phone, a size of a board has been limited and a multi-function of the electronic apparatus has been demanded. Therefore, it is required to mount electronic components for implementing more functions in a limited area of the board.

However, since a mounting area of the electronic components may not be sufficiently secured due to the limitation of the size of the board, a technology of inserting electronic components such as an active device, for example, an integrated circuit (IC), a semiconductor chip, a passive device, and the like, has been demanded. Recently, a technology of embedding the active device and the passive device in the same layer or stacking the active device and the passive device and then embedding the stacked active device and passive device in a board has been developed.

Generally, in a method of manufacturing a printed circuit board in which components are embedded, a cavity is formed in a core of a board, and various devices and electronic components such as an IC, a semiconductor chip, and the like, are inserted into the cavity. Then, a resin material such as prepreg, or the like, is applied into the cavity and onto the core into which the electronic components are inserted to fix the electronic components and form an insulating layer. A via hole or a through-hole is formed in the insulating layer and a circuit is formed by plating to allow the electronic components to be electrically conducted to the outside of the board.

Here, circuit patterns are formed in and on the via hole and the through-hole by the plating and are used as an electrical connection unit with the electronic components embedded in the board, and the insulating layers are sequentially stacked on upper and lower surface of the board, thereby making it possible to manufacture a multilayer printed circuit board in which the electronic components are embedded.

However, in the case in which impact is applied to the electronic component in a state in which the electronic component is mounted on the printed circuit board in which a plurality of insulating layers are stacked, for example, in the case in which the electronic component drops on a ground, warpage is instantaneously generated in the board. In this process, a crack is generated in the printed circuit board, such that a lifespan of the electronic component is decreased.

As the number of chips per unit area of the printed circuit board is increased, the generation of the crack is intensified. In addition, the above-mentioned problems cannot but be intensified since a thickness of the board has been gradually decreased.

### SUMMARY OF THE INVENTION

An object of the present invention is to provide a printed circuit board capable of expecting an increase in durability by forming a crack preventing port between a plurality of stacked insulating layers to decrease generation of a crack due to external impact.

According to an exemplary embodiment of the present invention, there is provided a printed circuit board including: an insulating layer part having at least one pair of insulating layers stacked therein; circuit patterns formed on the insulating layers, respectively; and crack preventing ports formed at positions at which they are not affected by the respective circuit patterns of the insulating layer part and supporting the insulating layer part from external impact.

The crack preventing ports may be installed at support parts of the insulating layer part.

The insulating layer part may include a chip formed thereon through solder balls, and the crack preventing ports may be formed under outer solder balls among the solder balls.

The crack preventing port may have any one of a cylindrical shape and a via shape supporting between the respective insulating layers.

The crack preventing port may be formed by forming a hole in the insulating layer part using any one of a laser and a drill and then filling the hole with a plating material.

### BRIEF DESCRIPTION OF THE DRAWINGS

FIG. 1 is an illustrative diagram showing a lateral cross section of a printed circuit board according to an exemplary embodiment of the present invention;

FIG. 2 is an illustrative diagram showing the printed circuit board according to the exemplary embodiment of the present invention when being viewed from the top; and

FIG. 3 is an illustrative diagram showing a process of supporting impact in a state in which stress is concentrated on the printed circuit board according to the exemplary embodiment of the present invention.

### DESCRIPTION OF THE PREFERRED EMBODIMENTS

Hereinafter, exemplary embodiments of the present invention will be described in detail with reference to the accompanying drawings.

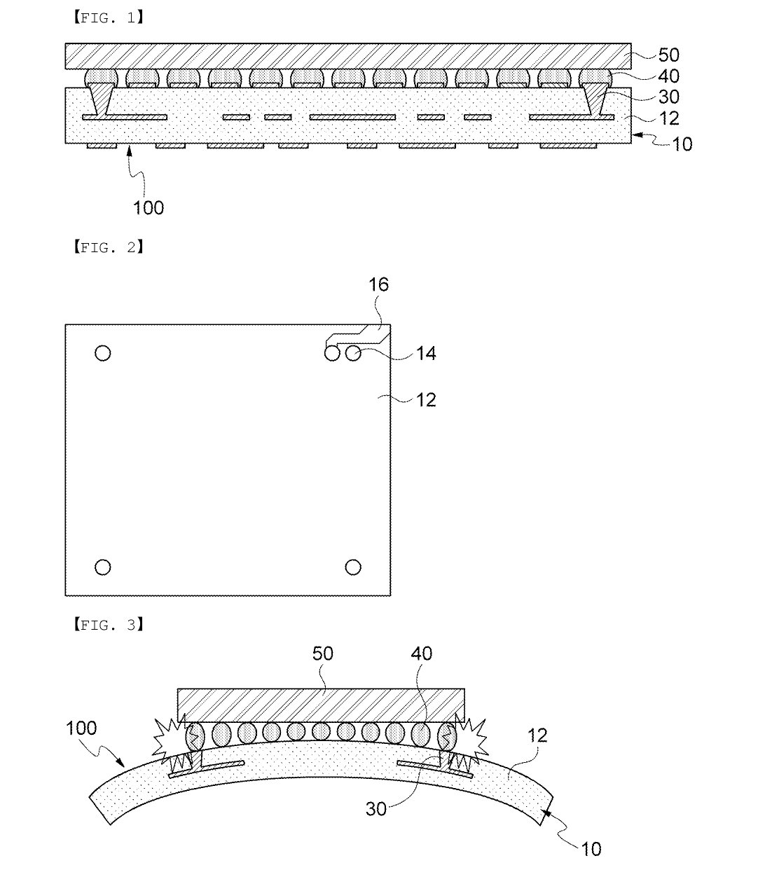

FIG. 1 is an illustrative diagram showing a lateral cross section of a printed circuit board according to an exemplary embodiment of the present invention; FIG. 2 is an illustrative diagram showing the printed circuit board according to the exemplary embodiment of the present invention when being viewed from the top; and FIG. 3 is an illustrative diagram showing a process of supporting impact in a state in which stress is concentrated on the printed circuit board according to the exemplary embodiment of the present invention.

As shown, the printed circuit board 100 according to the exemplary embodiment of the present invention is configured to include an insulating layer part 10 having at least one pair of insulating layers 12 stacked therein, circuit patterns 16 formed on the insulating layers 12, respectively, and crack preventing ports 30 formed at positions at which they are not affected by the circuit patterns 16.

The insulating layer part 10 in which at least one pair of insulating layers 12 having the circuit patterns formed thereon are stacked may include a plurality of insulating layers 12 stacked therein according to a specification of an electronic product for implementing more slimness.

Particularly, recently, a thickness of an electronic product such as a mobile product tends to be minimized and an area thereof tends to be increased. Therefore, the insulating layer part 10 may be designed and manufactured so as to correspond to these trends.

A chip 50 such as a power management integrated chip (PMIC) for supplying power may be mounted on the insulating layer 12 disposed at the uppermost portion of the insulating layer part 10. The chip 50 may be installed on the insulating layer 12 through solder balls 40.

In this case, the respective insulating layers 12 are provided with the circuit patterns so as to be electrically connected to the solder balls 40.

In addition, the insulating layer part 10 may include support parts 14 formed at positions at which they are not affected by the circuit patterns 16 of the upper insulating layer 12, that is, predetermined positions at which the circuit patterns 16 are not formed.

The support parts 14, which indicate positions at which the crack preventing ports 30 are installed, may be formed under the outermost solder balls 40 among the solder balls 40 formed on the insulating layer 12.

The crack preventing port 30 may be formed at the support part 14 as described above by forming a hole (not shown) using any one of a laser and a drill and then filling the hole with a plating material.

The hole may be perforated from the uppermost insulating layer 12 up to an upper portion of the insulating layer 12 closely adhered to a lower portion. However, in the case in which the circuit patterns are not formed on the insulating layer 12 closely adhered to the lower portion, the hole may also be perforated up to the insulating layer 12 positioned at the lower portion.

The crack preventing port 30 supports the insulating layer part 10 from external impact, thereby making it possible to prevent damage to the insulating layer part 10 by firm fixing force even though stress is concentratively generated at a portion at which the solder ball 40 is formed.

That is, the crack preventing ports 30 formed by forming holes in the insulating layer 12 under the solder balls disposed at an outer side among a plurality of solder balls 40 using the laser or the drill and then filling the formed holes with the plating material firmly support the sides of the insulating layer part 10, thereby making it possible to secure firm supporting force between the solder balls 40 and the insulating layer part 10 even though the external impact is applied.

Here, the crack preventing port 30 according to the exemplary embodiment of the present invention may have the entire shape in which a diameter thereof becomes narrower from an upper portion thereof toward a lower portion thereof. However, the crack preventing port 30 is not limited to have the above-mentioned shape, but may have any shape capable of performing the same function, such as a cylindrical shape, or the like.

When impact such as a drop is applied from the outside to the printed circuit board 100 according to the exemplary embodiment of the present invention configured as described above after the chip 50 is mounted on the insulating layer part 10, warpage is generated in the insulating layer part 10.

Here, in the case in which the number of chips per unit area is large, the thinner the thickness of the insulating layer part, the larger the warpage generated in the insulating layer part 10.

When the warpage is instantaneously generated in the insulating layer part 10 as described above, larger stress is concentratively generated at a portion at which the insulating layer part 10 and the solder balls 40 are bonded to each other based on the center of the insulating layer part 10.

As described above, when the stress is concentrated on the bonded portion, it may damage the upper insulating layer 12 of the insulating layer part 10 to short-circuit the circuit patterns 16 of the insulating layer.

Therefore, the crack preventing port 30 according to the exemplary embodiment of the present invention supports the insulating layer part 10 so that the stress applied to the insulating layer part 10 is not transferred to the insulating layer part 10, thereby making it possible to prevent damage to the insulating layer 12.

In other words, in a process in which the stress is applied to the insulating layer part 10, the crack preventing port 30 is made of a metal material having hardness higher than that of the insulating layer part 10 and is formed under the outermost solder ball among the solder balls 40, thereby making it possible to effectively block the stress directed toward an inner portion of the insulating layer part 10.

Since the crack preventing port 30 may minimize or prevent the damage to the insulating layer part 10 as described above, a problem such as a short-circuit of the insulating layer part 10 due to external impact may be prevented.

The printed circuit board according to the exemplary embodiment of the present invention includes the crack preventing ports for supporting impact formed between a plurality of insulating layers to decrease generation of a crack due to external impact, thereby making it possible to increase durability.

Hereinabove, although the printed circuit board according to the exemplary embodiment of the present invention has been described, the present invention is not limited thereto, but may be variously modified and altered by those skilled in the art.

What is claimed is:

1. A printed circuit board comprising:
an insulating layer part having at least one pair of insulating layers stacked therein;
circuit patterns formed on the insulating layers, respectively; and
crack preventing ports formed at positions at which they are not affected by the respective circuit patterns of the insulating layer part and supporting the insulating layer part from external impact.

2. The printed circuit board according to claim 1, wherein the crack preventing ports are installed at support parts of the insulating layer part.

3. The printed circuit board according to claim 1, wherein the insulating layer part includes a chip formed thereon through solder balls, and the crack preventing ports are formed under outer solder balls among the solder balls.

4. The printed circuit board according to claim 1, wherein the crack preventing port has any one of a cylindrical shape and a via shape supporting between the respective insulating layers.

5. The printed circuit board according to claim 1, wherein the crack preventing port is formed by forming a hole in the insulating layer part using any one of a laser and a drill and then filling the hole with a plating material.
